(19) United States
(12) Patent Application Publication
(10) Pub. No.: US 2014/0133102 A1
(43) Pub. Date: May 15, 2014

(54) HEAT DISSIPATING ASSEMBLY AND ELECTRONIC DEVICE ASSEMBLY WITH HEAT DISSIPATING ASSEMBLY

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: ER-WEI LU, Shenzhen (CN); XIANG-KUN ZENG, Shenzhen (CN); CHENG HAO, Shenzhen (CN)

(21) Appl. No.: 13/931,526

(22) Filed: Jun. 28, 2013

(30) Foreign Application Priority Data
Nov. 13, 2012 (CN) 2012104526750

(51) Int. Cl. H05K 7/20; F28F 3/00

(52) U.S. Cl. CPC H05K 7/20336; F28F 3/00
USPC 361/700; 165/185

(57) ABSTRACT

An electronic device assembly includes an electronic device, an internal heat dissipating mechanism, an external heat dissipating mechanism, and the heat dissipating mechanism. The electronic device includes a bottom base, and the internal heat dissipating mechanism is secured inside the bottom base, to dissipate heat generated by the electronic device. The external heat dissipating mechanism is secured outside the bottom base. The heat conduction block is secured to the internal heat dissipating mechanism and contacts with the external heat dissipating mechanism. The heat conduction block directs heat from the internal heat dissipating mechanism, and the external heat dissipating mechanism directs heat from the heat conduction block, to increase the heat dissipating efficiency of the internal heat dissipating mechanism, to make the electronic device work in a proper temperature.

### BACKGROUND

1. Technical Field

The present disclosure relates to electronic device assemblies, more particularly to an electronic device assembly with a heat dissipating assembly.

2. Description of Related Art

Heat dissipating devices perform the critical function of removing heat from an electronic device. The electronic device, such as a portable computer, always includes a heat dissipating mechanism. For example, the heat dissipating mechanism is provided with a fan, a fin assembly and a pipe. The pipe conducts heat away from the number of heat generating parts to the fin assembly, and then airflow is directed out of the electronic device by the fan, for dissipating heat generated in the electronic device. However, a heat dissipating efficiency of the heat dissipating mechanism is very low and cannot satisfy high performance and speed of the portable computer.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an electronic device assembly in accordance with an embodiment, and the electronic device assembly including an electronic device, an internal heat dissipating mechanism, an external heat dissipating mechanism and a heat conduction block.

FIG. 2 is an isometric view of the internal heat dissipating mechanism and the heat conduction of FIG. 1.

FIG. 3 is an isometric view of the external heat dissipating mechanism of FIG. 1.

FIG. 4 is an assembled view of the electronic device assembly of FIG. 1, but a keyboard is not showing.

FIG. 5 is another assembled view of the electronic device assembly of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

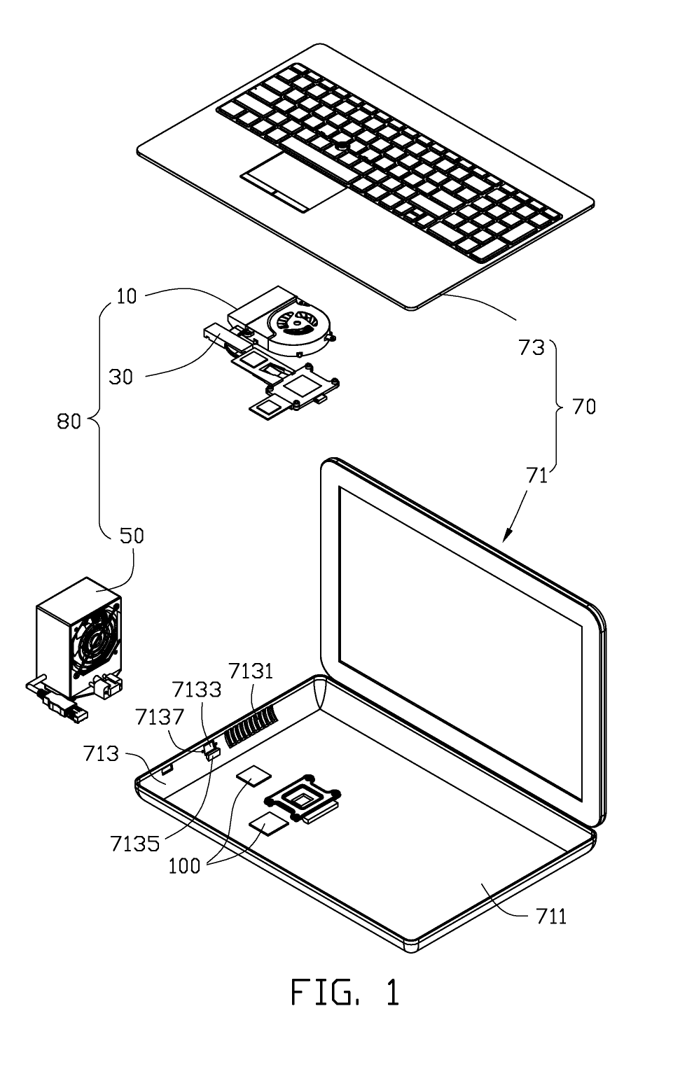

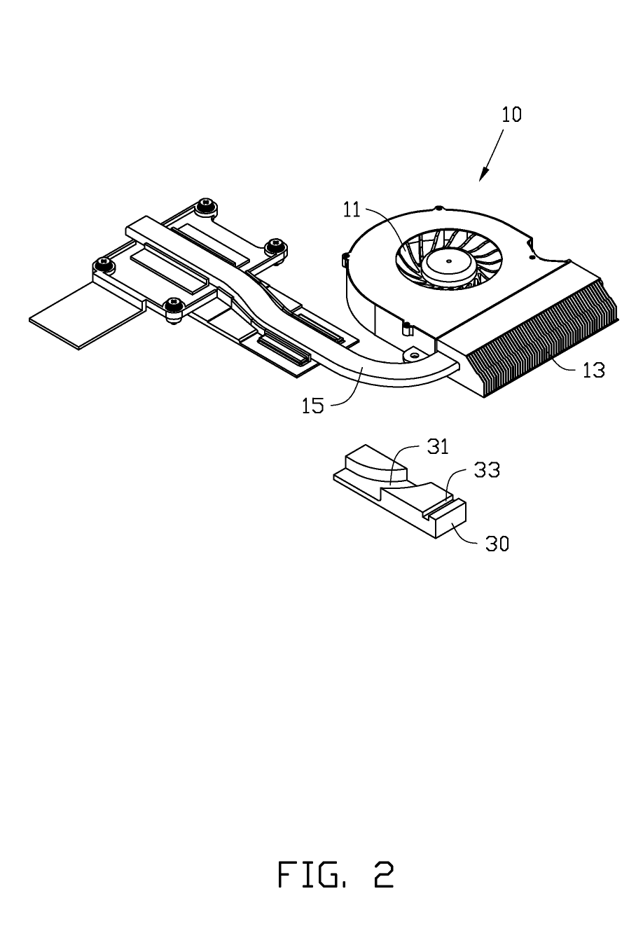

FIGS. 1 and 2 show an electronic device assembly in accordance with an embodiment. The electronic device assembly includes an electronic device 70 and a heat dissipating assembly 80 secured to the electronic device 70. In one embodiment, the electronic device 70 may be a portable computer, for example.

The electronic device 70 includes a bottom base 71 and an integrally formed keyboard 73, in other embodiments the keyboard 73 may be coupled to the bottom base 71. The bottom base 71 includes a bottom plate 711 and a sidewall 713 connected to the bottom plate 711. The sidewall 713 defines a ventilation area 7131 and a through hole 7133 located on one side of the ventilation area 7131. A latch tab 7135 extends upwards from a bottom edge of the through hole 7133, corresponding to the heat dissipating assembly 80. Two locking holes 7137 are defined in two opposite sides of the through hole 7133. A motherboard (not shown) is installed on the bottom plate 111, and a plurality of heat generating parts 100 are attached to the motherboard.

The heat dissipating assembly 80 includes an internal heat dissipating mechanism 10, an external heat dissipating mechanism 50, and a heat conduction block 30 attached to the internal heat dissipating mechanism 10. The internal heat dissipating mechanism 10 is received in the electronic device 70, to dissipate heat generated by the plurality of heat generating parts 100, and the external heat dissipating mechanism 50 is installed on outside of the electronic device 70, to dissipate heat of the internal heat dissipating mechanism 10.

The internal heat dissipating mechanism 10 includes a first fan 11, a first fin assembly 13, and a first heat pipe 15. The first fin assembly 13 is located on one side of the first fan 11. A first end of the heat first pipe 15 is inserted into the first fin assembly 13, and a second end opposite to the first end of the first heat pipe 15 closely abuts the plurality of heat generating parts 100.

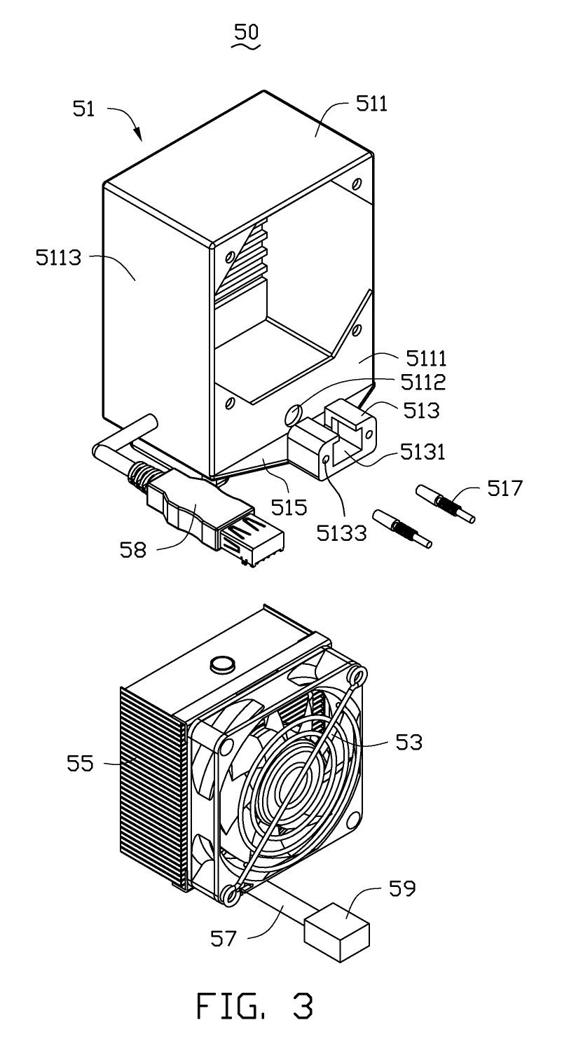

FIG. 3 shows that the external heat dissipating mechanism 50 includes a bracket 51, a second fan 53, a second fin assembly 55, a second heat pipe 57, and a heat diffusion block 59. The bracket 51 includes a box body 511, a clipping portion 513, and a connecting piece 515. The box body 511 includes a front plate 5111 and a side plate 5113 connected to the side plate 5113, configured to receive the second fan 53 and the second fin assembly 55. The front plate 5111 defines an exit hole 5112 corresponding to the second heat pipe 57. The connecting piece 515 extends from a bottom edge of the front plate 5111, adjacent to the exit hole 5112. The clipping portion 513 defines a clipping slot 5131 for receiving the heat diffusion block 59. Two securing holes 5133 are defined in the clipping portion 513 and are located at opposite sides of the clipping slot 5131, corresponding to the two locking holes 7137 of the electronic device 70. A connector 58 is connected to the second fan 53 and the electronic device 70, providing power to the second fan 53.

FIG. 2 shows that, the heat conduction block 30 defines a receiving slot 31 for receiving the first heat pipe 15. A latch slot 33 is defined in the heat conduction block 30, for receiving the latch tab 7135.

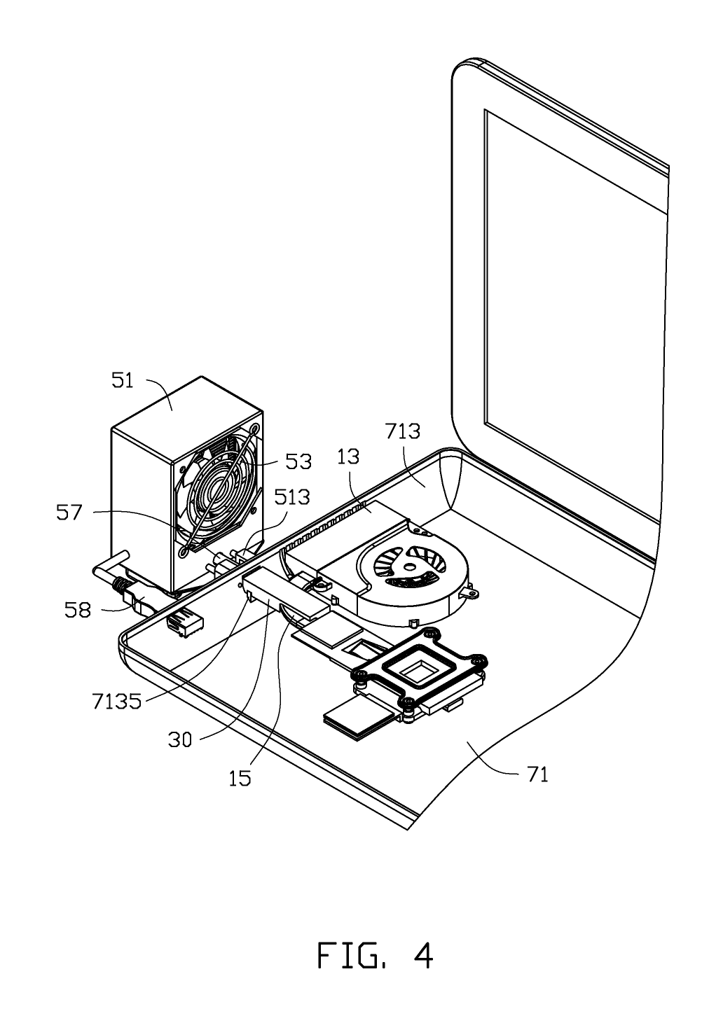

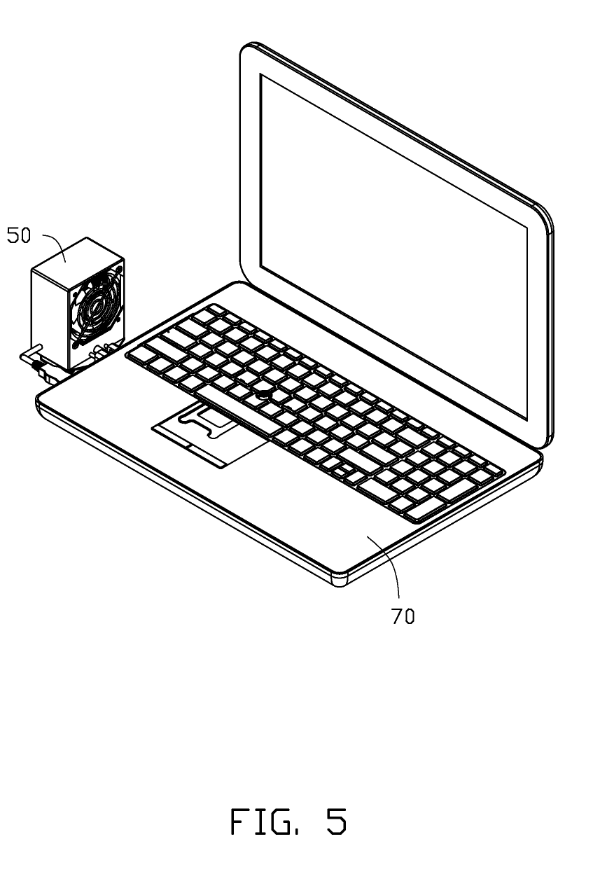

FIGS. 4 and 5 illustrates that in assembly, the receiving slot 31 of the heat conduction block 30 receives the first heat pipe 15 and closely contacts with the first heat pipe 15. In one embodiment, the heat conduction block 30 is sealed on the first heat pipe 15. The internal heat dissipating mechanism 10 and the heat conduction block 30 are installed on the bottom plate 711. A latch tab 7135 is engaged in the latch slot 33 of the heat conduction block 30, and the latch tab 7135 partly extends through the through hole 7133. The first fin assembly 13 is aligned with the ventilation area 7131, and the first fan 11 guides airflow to the outside of the electronic device 70 via the ventilation area 7131.

The second fan 53 and the second fin assembly 55 are received in the box body 511. One end of the second heat pipe 57 is inserted into the second fin assembly 55, and another end of the second heat pipe 57 extends through the exit hole 5112 to connect to the heat diffusion block 59. The heat diffusion block 59 is partly engaged in the clipping slot 5131.

The external heat dissipating mechanism 50 is placed on the outside of the electronic device 70. The clipping portion 513 abuts an outer surface of the sidewall 713, and the heat diffusion block 59 closely contacts with the heat conduction block 30. Each of the two securing holes 5133 of the clipping portion 513 is aligned with each of the two locking holes 7137 of the bottom base 71, and two thumb screws 517 are locked into the two securing holes 5133 and the two locking holes 7137. The external heat dissipating mechanism 50 is thereby installed on the electronic device 70.

In use, the first heat pipe 15 directs heat generated by the plurality of heat generating parts 100 along a first direction to the first fin assembly 13, and along a second direction to the second heat pipe 57 via the heat conduction block 30. In one embodiment, the first direction is substantially perpendicular to the second direction. The second heat pipe 57 directs heat to the second fin assembly 55, and the second fan 53 guides airflow around the second fin assembly 55 to dissipate heat. A heat dissipating efficiency of the external heat dissipating mechanism is thereby increased.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A heat dissipating assembly comprising:
an internal heat dissipating mechanism configured to be secured inside an electronic device and capable of dissipating heat generated by the electronic device;
an external heat dissipating mechanism configured to be secured outside the electronic device; and
a heat conduction block secured to the internal heat dissipating mechanism and in contact with the external heat dissipating mechanism,
wherein the heat conduction block directs heat from the internal heat dissipating mechanism to the external heat dissipating mechanism.

2. The heat dissipating assembly of claim 1, wherein the internal heat dissipating mechanism comprises a first heat pipe configured to direct heat from the electronic device to the heat conduction block, the external heat dissipating mechanism comprises a second heat pipe, the heat conduction block is attached to the first heat pipe, and the second heat pipe contacts with the heat conduction block, to dissipate heat from the heat conduction block.

3. The heat dissipating assembly of claim 2, wherein the heat conduction block defines a receiving slot, and the first heat pipe is received in the receiving slot and contacts the first heat pipe.

4. The heat dissipating assembly of claim 3, wherein the heat conduction block defines a latch slot, and the latch slot is configured to engage with the electronic device.

5. The heat dissipating assembly of claim 2, wherein the external heat dissipating mechanism further comprises a heat diffusion block and a second fin assembly, a first end of the second heat pipe is received in the second fin assembly, and a second end opposite to the first end of the second heat pipe is connected to the heat diffusion block.

6. The heat dissipating assembly of claim 5, wherein the heat diffusion block abuts the heat conduction block and directs heat from the heat conduction block to the second heat pipe.

7. The heat dissipating assembly of claim 5, wherein the external heat dissipating mechanism further comprises a bracket, the bracket comprises a clipping portion defining a clipping slot, and the heat diffusion block is received in the clipping slot.

8. The heat dissipating assembly of claim 7, wherein the bracket further comprises a box body and a second fan, and the second fan and the second fin assembly are received in the box body.

9. The heat dissipating assembly of claim 8, wherein the bracket further comprise a connecting piece, and the connecting piece is connected the clipping portion with the box body.

10. An electronic device assembly comprising:
an electronic device comprising a bottom base; and
a heat dissipating assembly comprising:
an internal heat dissipating mechanism secured inside the bottom base and dissipating heat generated by the electronic device;
an external heat dissipating mechanism secured outside the bottom base; and
a heat conduction block secured to the internal heat dissipating mechanism and contacting with the external heat dissipating mechanism,
wherein the heat conduction block directs heat from the internal heat dissipating mechanism, and the external heat dissipating mechanism directs heat from the heat conduction block.

11. The electronic device assembly of claim 10, wherein the internal heat dissipating mechanism comprises a first heat pipe directing heat from the electronic device to the heat conduction block, the external heat dissipating mechanism comprises a second heat pipe, the heat conduction block is attached to the first heat pipe, and the second heat pipe contacts with the heat conduction block, to dissipate heat from the heat conduction block.

12. The electronic device assembly of claim 11, wherein the heat conduction block defines a receiving slot, and the first heat pipe is received in the receiving slot and closely contacts with the first heat pipe.

13. The electronic device assembly of claim 11, wherein the heat conduction block defines a latch slot, the bottom base comprises a sidewall, a latch tab is located on the sidewall, and the latch tab is received in the latch slot.

14. The electronic device assembly of claim 13, wherein the external heat dissipating mechanism further comprises a heat diffusion block and a second fin assembly, one end of the second heat pipe is received in the second fin assembly, and another end of the second heat pipe is connected to the heat diffusion block.

15. The electronic device assembly of claim 14, wherein the sidewall defines a through hole, the heat conduction block partially extends through the through hole to abut the heat diffusion block, and the heat diffusion block directs heat from the heat conduction block to the second heat pipe.

16. The electronic device assembly of claim 14, wherein the external heat dissipating mechanism further comprises a bracket, the bracket comprises a clipping portion defining a clipping slot, and the heat diffusion block is received in the clipping slot.

17. The electronic device assembly of claim 16, wherein the clipping portion defines two securing holes located on opposite sides of the clipping slot, and the sidewall defines two locking holes, and two thumb screws are locked into the two securing holes and the two locking holes, to secure the external heat dissipating mechanism to the bottom base.

18. The electronic device assembly of claim 16, wherein the bracket further comprises a box body and a second fan, and the second fan and the second fin assembly are received in the box body.

19. The electronic device assembly of claim 18, wherein the bracket further comprise a connecting piece, and the connecting piece is connected the clipping portion with the box body.
